(19) United States
(12) Patent Application Publication
(10) Pub. No.: US 2021/0181236 A1
(43) Pub. Date: Jun. 17, 2021

(54) SPRING PROBE WITH HIGH STABILITY

(71) Applicant: Suzhou UIGreen Micro&Nano Technologies Co.,Ltd., Suzhou (CN)

(72) Inventors: Xiaochen QIAN, SUZHOU (CN); Xingshun LUO, SUZHOU (CN)

(21) Appl. No.: 16/924,376

(22) Filed: Jul. 9, 2020

(30) Foreign Application Priority Data
Dec. 12, 2019 (CN) 201922218517.9

(51) Int. Cl. G01R 1/067

(52) U.S. Cl. CPC G01R 1/06722; G01R 1/06738

(57) ABSTRACT

The application provides a spring probe with high stability, which comprises a hollow syringe with a spring in it. The upper end and the lower end of the syringe has an upper thimble and a lower thimble respectively. There are two support rings at the outer clearance of the syringe, and a group of flanges for positioning the support rings at two sides of each support ring. The advantages of this application are that: the support ring can ensure that the spring probe is better fixed in the fixed plate without being pressed out, thereby better ensuring that the spring probe does not deviate beyond the tolerance range when used, and obviously improving the high frequency bandwidth by the support ring with low relative dielectric constant.

### CROSS-REFERENCE TO RELATED APPLICATIONS

This application claims priority to Chinese Patent Applications No. CN201922218517.9 with a filing date of Dec. 12, 2019. The content of the aforementioned application, including any intervening amendments thereto, are incorporated herein by reference.

### FIELD OF THE INVENTION

This application relates to the technical field of semiconductor components, and particularly relates to a spring probe with high stability.

### BACKGROUND

With the rapid development of the technology in semiconductor chips, the technical requirements of the chip test socket, which plays an important role in the process of chip development and mass production, are also continuously improving, especially the key part of the socket: spring probe.

The test socket mainly comprises a chip guide set, a probe fixing plate and a spring probe. The guide set can ensure the accurate position of the chip when the chip is placed in the socket for testing, the probe fixing plate is used for fixing the probe between the chip and the PCB and ensures that the position of the probe in the socket corresponds to the contact point on the PCB one by one, and the probe ensures stable mechanical conduction between the chip and the PCB and has corresponding electrical performance. Wherein the guide set can be integrated with the probe fixing plate. In order to avoid cut-off between probes and other influences on the test, the guide set and probe fixing plate are mostly made of insulating materials such as plastic and ceramic. The spring probe, as a key component connecting the chip and PCB board, can provide elastic stable contact and transmit current and signals. It is divided into single-action needles or double-action needles, but all are assembled by metal parts.

With the fulfillment of Moore's Law, the requirements of signal transmission frequency and bandwidth in the chip are also getting higher and higher. The traditional socket performance based on spring probe testing has encountered severe challenges. New test probes with higher performance and corresponding test sockets are urgently needed to meet the high frequency requirements.

### BRIEF DESCRIPTION OF THE DRAWINGS

Various embodiments in accordance with the present disclosure will be described with reference to the drawings, in which:

FIG. 1 illustrates structural explosion diagram of the spring probe.

FIG. 2 illustrates the schematic diagram of the assembly structure.

FIG. 3 illustrates enlarged schematic diagram of the structure A in FIG. 2.

FIG. 4 illustrates enlarged schematic diagram of the structure B in FIG. 2.

FIG. 5 illustrates the schematic structural diagram of the support ring.

FIG. 6 illustrates the schematic structural diagram of the support ring of another structure.

### SUMMARY OF THE INVENTION

The application provides a spring probe with high stability to solve the defects of the prior art.

The aim of the application is realized by the following technical scheme:

The application relates to a spring probe with high stability, which comprises a hollow syringe, wherein a spring is set in the syringe; the upper end and the lower end of the syringe are respectively set with an upper thimble and a lower thimble; two support rings are sleeved at the outer clearance of the syringe; and two sides of each support ring are set with a group of flanges for positioning the support rings.

Preferably, there is a flange with a diameter larger than the outer diameter of the syringe at the upper thimble. It forms an upper flange group together with the flange at the clearance of the upper end of the syringe. The clearance at the lower end of the syringe is set with two flanges to form a lower flange group.

Preferably, the lower end of the upper thimble is set in the syringe and riveted and fixed with the syringe.

Preferably, the bottom diameter of the upper thimble is larger than the outer diameter of the spring.

Preferably, the diameter of the upper end of the lower thimble is larger than the outer diameter of the spring, the upper end of the lower thimble penetrates through the syringe, and the lower thimble is forced to axially compress the spring.

Preferably, grooves are uniformly distributed on the outer peripheral surface of the support ring.

Preferably, the periphery of the flange is provided with chamfers for assisting the bracket to be sleeved.

Preferably, the support rings are plastic.

Preferably, the flange diameter at the proximal end of the support ring is smaller than that at the distal end of the support ring.

The advantages of this application are that: the support ring can ensure that the spring probe is better fixed in the fixed plate without being pressed out, thereby better ensuring that the spring probe does not deviate beyond the tolerance range when used, and obviously improving the high frequency bandwidth by the support ring with low relative dielectric constant.

### DETAILED DESCRIPTION OF THE INVENTION

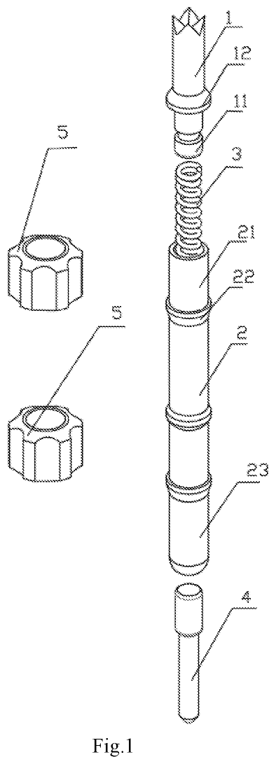

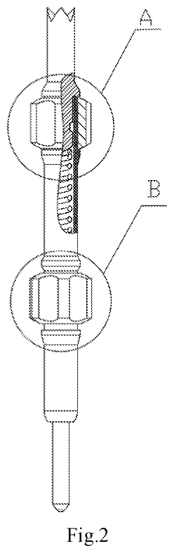

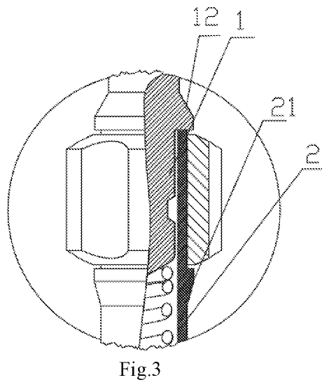

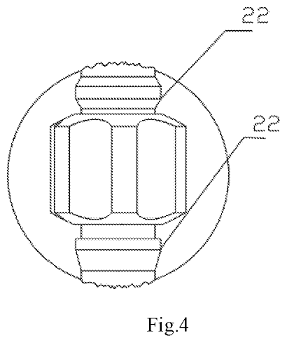

The technical scheme of the application was described in detail with reference to embodiment. The application discloses a spring probe with high stability as shown in FIGS. 1-4, comprising a hollow syringe 2, wherein a spring 3 is set in the syringe 2, and the upper and lower ends of the syringe 2 are respectively set with an upper thimble 1 and a lower thimble 4.The lower end 11 of the upper thimble 1 is set in the syringe 2 and riveted and fixed with the syringe 2, and the bottom diameter of the upper thimble 1 is larger than the outer diameter of the spring 3. The diameter of the upper end of the lower thimble 4 is larger than the outer diameter of the spring 3, and the upper end of the lower thimble 4 penetrates through the syringe 2, which is similar to a spring probe in the prior art. There is a certain movable space in the syringe 2, and when the lower thimble 4 is stressed, the spring 3 can be axially compressed.

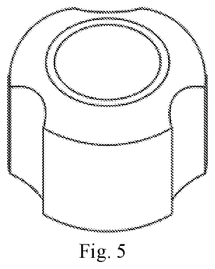

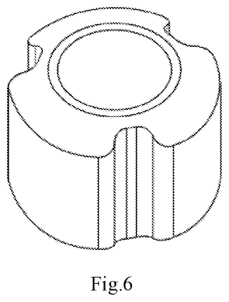

The spring probe also comprises two plastic support rings 5 sleeved on the syringe 2. The plastic is made of the copolymer of perfluoropropyl, perfluorovinyl ether and polytetrafluoroethylene, and the relative dielectric constant of the material is low, so that the material can show more excellent high-frequency performance in the coaxial transmission process. As shown in FIGS. 5-6, grooves are uniformly distributed on the outer peripheral surface of the support rings 5 to form butterfly wings which makes the outer surface of the support ring 5 is easy to hold. There are three grooves in the figures, and the actual number of grooves can be adjusted according to requirements. Similarly, radial protrusion processing can be carried out in the groove as required.

Two sides of each support ring are set with a group of flanges for positioning the support ring. Specifically, the upper thimble 1 is set with an upper flange 12 with a diameter larger than the outer diameter of the syringe 2, and the syringe 2 is set with three flanges 22, wherein one flange 22 is matched with the upper flange 12 of the upper thimble 1 to serve as an upper flange group for positioning the support ring 5, i.e., one support ring 5 is placed in the upper flange group. The lower end clearance of the syringe 2 is set with two flanges 22 to form a lower flange group for positioning the other support ring 5. In order to enable the support ring 5 to smoothly enter into the flange group and fix the position, the periphery of the flange is set with a slow-down chamfer 21 for assisting the support ring 5 to be sleeved. And the flange's diameter at the proximal end of the support ring is smaller than that at the distal end of the support ring. The structure of the flange can adopt a ladder-shaped cross section or a structure with small diameter at both ends and large diameter at the middle section.

The following briefly describes the assembly process of the spring probe of the present invention:

Firstly, rivet the upper thimblel with the syringe 2, and place the spring 3 and the lower thimble 4 in the syringe 2 respectively. Then, press the support rings 5 into the upper flange group and the lower flange group respectively with a jig to complete the assembly of the whole spring probe. When the probe is used for testing, its determining principle is consistent with that of the prior art, so it is not repeated here.

There are still many specific implementations of the application, which will not be listed here. All technical solutions by equivalent substitution or equivalent transformation are within the scope of the application.

We claim:

1. A spring probe with high stability, comprising:
a hollow syringe, wherein a spring is set in the syringe, an upper thimble and a lower thimble are respectively set at the upper end and the lower end of the syringe, two support rings are sleeved at the outer clearance of the syringe, and two sides of each support ring are set with a group of flanges for positioning the support rings.

2. The spring probe with high stability of claim 1, wherein:
there is a flange with a diameter larger than the outer diameter of the syringe at the upper thimble; it forms an upper flange group together with the flange at the clearance of the upper end of the syringe; the clearance at the lower end of the syringe is set with two flanges to form a lower flange group.

3. The spring probe with high stability of claim 1, wherein:
the lower end of the upper thimble is set in the syringe and riveted and fixed with the syringe.

4. The spring probe with high stability of claim 3, wherein:
the bottom diameter of the upper thimble is larger than the outer diameter of the spring.

5. The spring probe with high stability of claim 1, wherein:
the diameter of the upper end of the lower thimble is larger than the outer diameter of the spring, the upper end of the lower thimble penetrates into the syringe, and the lower thimble is forced to axially compress the spring.

6. The spring probe with high stability of claim 1, wherein:
the grooves are uniformly distributed on the outer peripheral surface of the support ring.

7. The spring probe with high stability of claim 3, wherein:
the periphery of the flange is set with chamfers for assisting the support ring to be sleeved.

8. The spring probe with high stability of claim 3, wherein:
the support rings are plastic.

9. The spring probe with high stability of claim 3, wherein:
the flange's diameter at the proximal end of the support ring is smaller than that at the distal end of the support ring.
